(19) United States
(12) Patent Application Publication
(10) Pub. No.: US 2015/0123287 A1
(43) Pub. Date: May 7, 2015

(54) SEMICONDUCTOR PACKAGE AND FABRICATION METHOD THEREOF AND SUBSTRATE AND PACKAGING STRUCTURE

(71) Applicant: Siliconware Precision Industries Co., Ltd, Taichung (TW)

(72) Inventors: Chu-Chi Hsu, Taichung (TW); Lung-Yuan Wang, Taichung (TW); Cheng-Chia Chiang, Taichung (TW); Chia-Kai Shih, Taichung (TW)

(73) Assignee: SILICONWARE PRECISION INDUSTRIES CO., LTD, Taichung (TW)

(21) Appl. No.: 14/133,868

(22) Filed: Dec. 19, 2013

(30) Foreign Application Priority Data
Nov. 5, 2013 (TW) 102140073

(51) Int. Cl. H01L 25/065; H01L 21/02; H01L 25/00; H01L 23/00; H01L 23/31; H01L 21/56

(52) U.S. Cl. CPC H01L 25/0657; H01L 23/3142; H01L 21/56; H01L 25/50; H01L 24/81; H01L 21/02057; H01L 2225/06517; H01L 2225/0652; H01L 2225/06555; H01L 2224/81911; H01L 2224/81801
USPC 257/777; 428/58; 438/107; 257/734

(57) ABSTRACT

A method for fabricating a semiconductor package is disclosed, which includes the steps of: providing a first substrate; disposing a second substrate on the first substrate through a plurality of supporting elements, wherein the second substrate has at least a cleaning hole penetrating therethrough; and performing a cleaning process to clean space between the second substrate and the first substrate through the cleaning hole, thereby preventing a popcorn effect from occurring when the first substrate is heated and hence preventing delamination of the semiconductor package. Further, the cleaning hole facilitates to disperse thermal stresses so as to prevent warping of the first and second substrates during a chip-bonding or encapsulating process, thereby overcoming the conventional drawbacks of cracking of the supporting elements and a short circuit therebetween.

### BACKGROUND OF THE INVENTION

1. Field of the Invention

The present invention relates to semiconductor packages, and more particularly, to a semiconductor package and a fabrication method thereof as well as a substrate and a packaging structure so as to improve the reliability.

2. Description of Related Art

Currently, electronic products are developed toward the trend of high density, high performance and miniaturization. Accordingly, various types of package on package (PoP) structures have been developed to meet the trend.

Generally, a conventional stack type semiconductor package has a first packaging structure and a second packaging structure that are stacked on one another and bonded together through an encapsulant. The first packaging structure has a first substrate and a first semiconductor element electrically connected to the first substrate. The second packaging structure has a second substrate and a second semiconductor element electrically connected to the second substrate. The second substrate is stacked on and electrically connected to the first substrate through a plurality of solder balls. The encapsulant is formed between the first substrate and the second substrate for encapsulating the solder balls.

FIGS. 1A to 1B′ are schematic cross-sectional and upper views showing a method for fabricating a conventional stack type semiconductor package. Referring to FIGS. 1A to 1B′, a first packaging structure 1a is provided, which has a first substrate 11 and a plurality of semiconductor elements 10 disposed on the first substrate 11. Then, a second substrate 12 is disposed on and electrically connected to the first packaging structure 1a through a plurality of solder balls 13. Thereafter, since the solder balls 13 comprise a flux, a deionized (DI) water cleaning process is performed to remove the flux. Then, a plurality of second semiconductor elements (not shown) are electrically connected to the second substrate 12.

Referring to FIGS. 1B and 1B′, the cleaning process is performed along directions X, Z of from top and sides toward the second substrate 12 and the solder balls 13. However, since the first substrate 11 is covered by the second substrate 12, the flux f is easily left on the first packaging structure 1a when driven by the DI water. Therefore, a popcorn effect may occur when the first packaging structure 1a is heated, thus easily resulting in delamination of the second substrate 12 from the first packaging structure 1a.

Further, warpage easily occurs to the first substrate 11 and the second substrate 12 during a chip-bonding or encapsulating process due to a CTE (Coefficient of Thermal Expansion) mismatch between the first substrate 11, the second substrate 12 and the solder balls 13. As such, stresses induced by thermal expansion and contraction and applied on the joints between the solder balls 13 and the first substrate 11 or the second substrate 12 can easily cause cracking of the solder balls 13 and even a short circuit therebetween.

Therefore, how to overcome the above-described drawbacks has become urgent.

### SUMMARY OF THE INVENTION

In view of the above-described drawbacks, the present invention provides a semiconductor package, which comprises: a first substrate; and a second substrate disposed on the first substrate through a plurality of supporting elements, wherein at least a notch is formed at an edge of the second substrate.

In the above-described package, the notch can be of a bent shape, a curved shape, a linear shape or a polygonal shape.

The present invention further provides a method for fabricating a semiconductor package, which comprises the steps of: providing a first substrate; disposing a second substrate on the first substrate through a plurality of supporting elements, wherein the second substrate has at least a cleaning hole penetrating therethrough; and performing a cleaning process to clean space between the second substrate and the first substrate through the cleaning hole.

The above-described method can further comprise cleaning the supporting elements through the cleaning process.

In the above-described method, a liquid such as water can be used for the cleaning process.

In the above-described method, the second substrate can have a plurality of substrate units and the cleaning hole can be formed at an edge of the substrate units. For example, the second substrate further has a connecting portion formed between and connecting the substrate units, and the cleaning hole is formed on the connecting portion. The connecting portion can serve as a cutting path.

In the above-described method, the cleaning hole can be of a cross shape, a circular shape, a strip shape or a polygonal shape.

In the above-described package and method, at least a semiconductor element can be disposed on the first substrate.

In the above-described package and method, each of the supporting elements can be a conductive element. The conductive element can comprise a solder material and a flux.

In the above-described package and method, at least an electronic element can be disposed on the second substrate.

In the above-described package and method, an encapsulant can be formed between the second substrate and the first substrate. The encapsulant can fill the space between the second substrate and the first substrate.

The present invention further provides a substrate, i.e., the above-described second substrate, which comprises: a plurality of substrate units; and a connecting portion formed between and connecting the substrate units and having at least a cleaning hole penetrating therethrough.

In the above-described substrate, the cleaning hole can be of a cross shape, a circular shape, a strip shape or a polygonal shape.

In the above-described substrate, the connecting portion can serve as a cutting path.

The present invention further provides a packaging structure, which comprises: a substrate having a plurality of substrate units and a connecting portion formed between and connecting the substrate units, wherein at least a cleaning hole is formed to penetrate the connecting portion; and an electronic element disposed on the substrate.

In the above-described structure, the electronic element can be a semiconductor element.

In the above-described structure, the cleaning hole can be of a cross shape, a circular shape, a strip shape or a polygonal shape.

In the above-described structure, the connecting portion can serve as a cutting path.

According to the present invention, a liquid can flow through the cleaning hole into the space between the first substrate and the second substrate, thereby increasing the liquid cleaning area. During the cleaning process, the liquid cleans residues such as flux from inside toward outside. As such, no residue is left on the first packaging structure after the cleaning process, thereby preventing a popcorn effect from occurring when the first substrate or the semiconductor element is heated and hence preventing delamination of the semiconductor package.

Further, the cleaning hole facilitates to disperse thermal stresses so as to prevent the first substrate and the second substrate from warping during a chip-bonding or encapsulating process, thereby reducing stresses induced by thermal expansion and contraction and applied on the joints between the supporting elements and the first substrate or the second substrate. Therefore, the present invention overcomes the conventional drawbacks of cracking of the supporting elements and a short circuit therebetween.

### BRIEF DESCRIPTION OF DRAWINGS

FIGS. 1A and 1B are schematic cross-sectional views showing a method for fabricating a semiconductor package according to the prior art, wherein FIG. 1B′ is an upper view of FIG. 1B; and

FIGS. 2A to 2E are schematic cross-sectional views showing a method for fabricating a semiconductor package according to the present invention, wherein FIG. 2B′ is an upper view of FIG. 2C, FIG. 2B′ shows another embodiment of FIG. 2B, FIG. 2C′ is a partially enlarged view of FIG. 2B, and FIGS. 2E′ and 2E″ are partial upper views showing different embodiments of FIG. 2E.

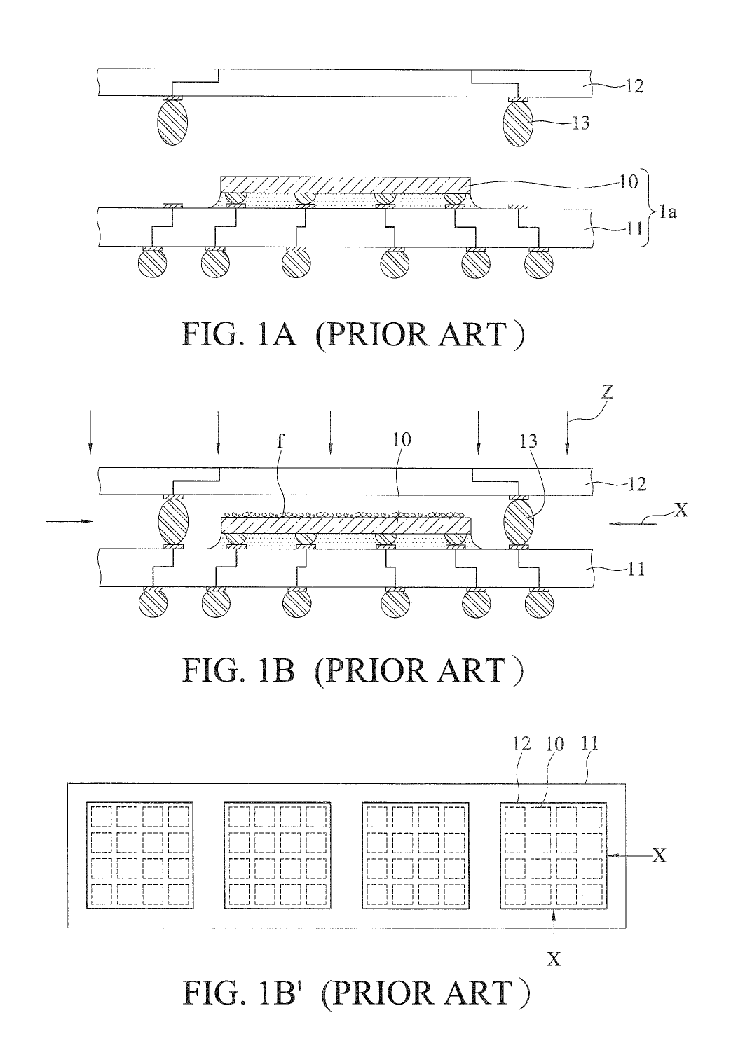

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “on”, “a” etc. are merely for illustrative purposes and should not be construed to limit the scope of the present invention.

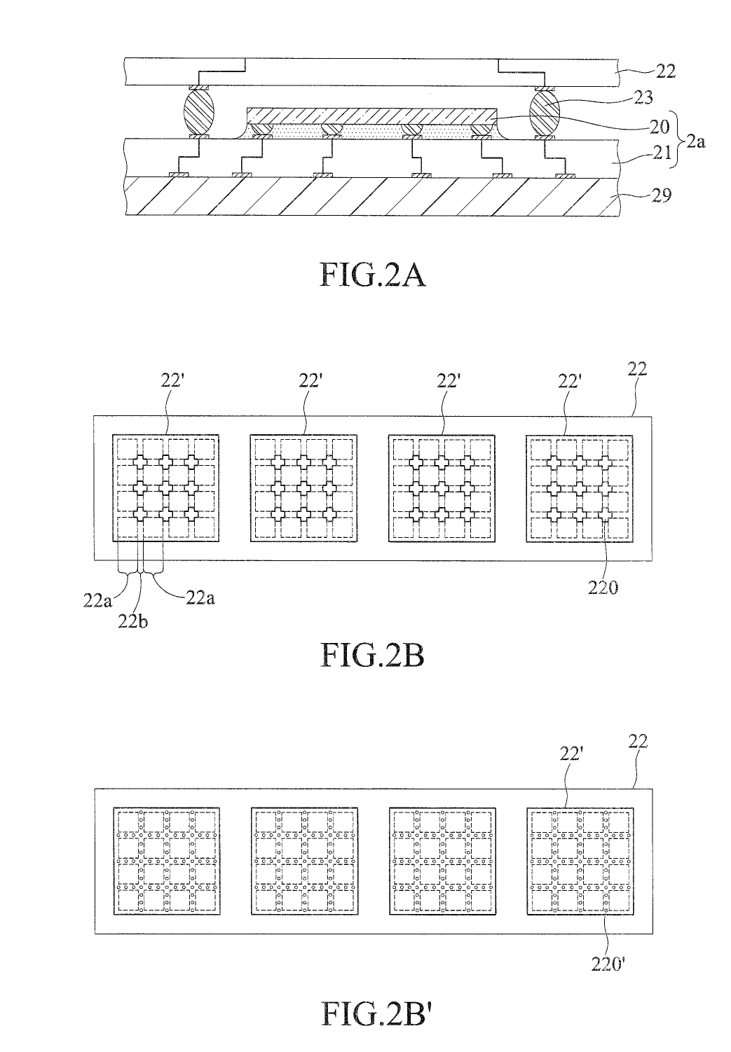

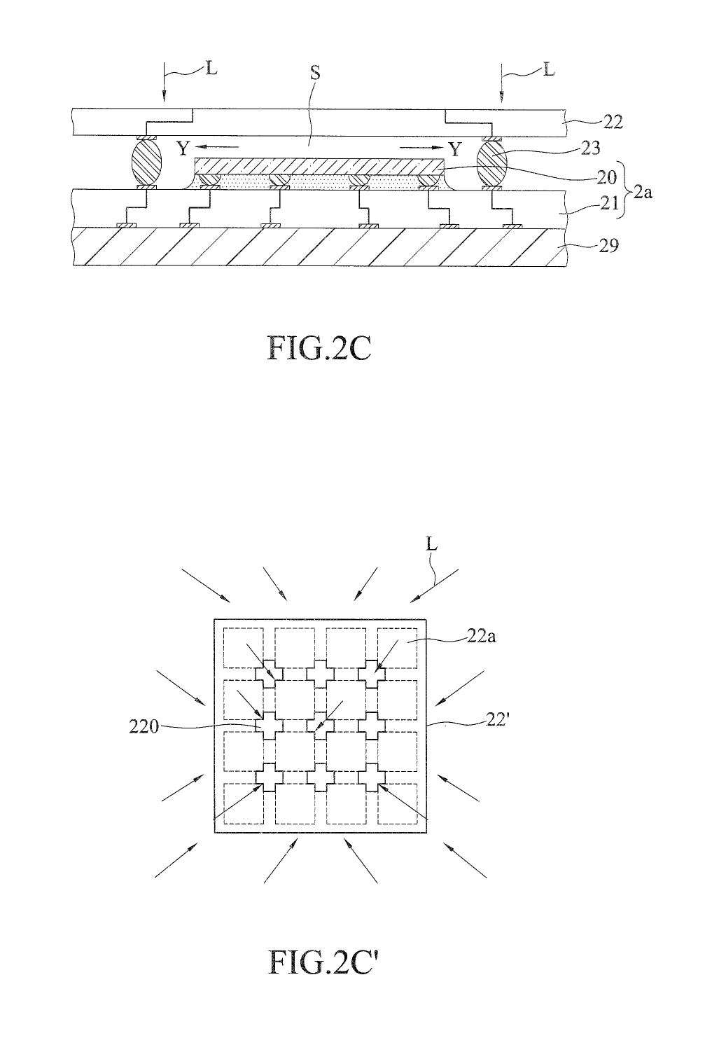

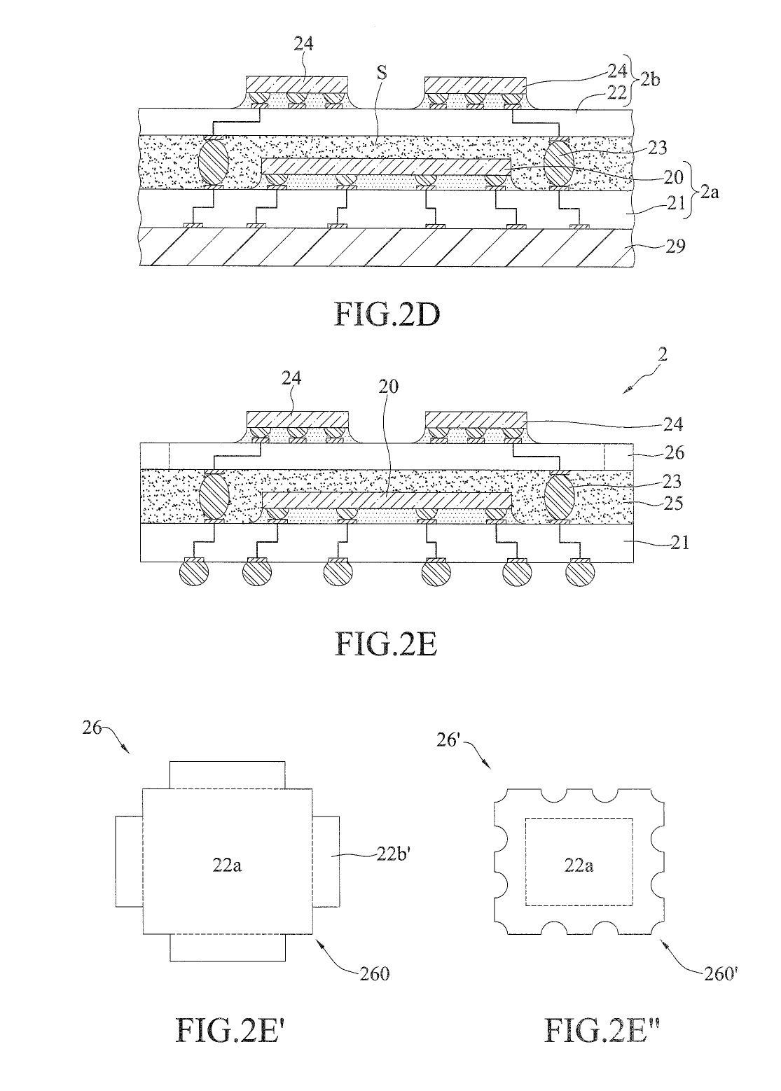

FIGS. 2A to 2E are schematic views showing a method for fabricating a semiconductor package 2 according to the present invention.

Referring to FIG. 2A, a first packaging structure 2a is provided, which has a first substrate 21 disposed on a carrier 29 and at least a semiconductor element 20 disposed on and electrically connected to the first substrate 21 in a flip-chip manner. Then, at least a second substrate 22 is disposed on the first substrate 21 through a plurality of supporting elements 23.

In the present embodiment, the first substrate 21 has a non-singulated full-panel structure having a plurality of semiconductor elements 20 disposed thereon. The second substrate 22 also has a non-singulated full-panel structure having four substrate blocks 22′, as shown in FIG. 2B.

Each of the substrate blocks 22′ has a plurality of substrate units 22a corresponding to the semiconductor elements 20 and a connecting portion 22b formed between and connecting the substrate units 22a. For example, as shown in FIG. 2B, each of the substrate blocks 22′ covers sixteen semiconductor elements 20.

Each of the supporting elements 23 is a conductive element. In particular, the conductive element comprises a solder material and a flux.

Further, the first substrate 21 and the second substrate 21 can be circuit boards.

Referring to FIGS. 2B and 2B′, a plurality of cleaning holes 220, 220′ are formed to penetrate the second substrate 22.

In the present embodiment, the cleaning holes 220, 220′ correspond in position to the semiconductor elements 20 and are located at edges of the substrate units 22a, for example, on the connecting portions 22b.

Each of the cleaning holes 220, 220′ can have a cross shape (as shown in FIG. 2B), a circular shape (as shown in FIG. 2B′), a strip shape or a polygonal shape.

Referring to FIGS. 2C and 2C′, a cleaning process is performed from top and sides toward the second substrate 22 and the supporting elements 23 to remove the flux and clean space S between the second substrate 22 and the first substrate 21 through the cleaning holes 220.

In the present embodiment, a liquid is used for the cleaning process. The liquid is water, such as DI water. The liquid is provided in a direction L of FIG. 2C′. Then, the liquid flows through the cleaning holes 220, 220′ into the space S between the second substrate 22 and the first substrate 21, thereby increasing the liquid cleaning area. During the cleaning process, the liquid cleans the flux from inside toward outside (in a direction Y of FIG. 2C). As such, no flux is left on the first packaging structure 2a after the cleaning process, thereby preventing a popcorn effect from occurring when the first packaging structure 2a is heated and hence effectively preventing delamination of the stack-type semiconductor package 2.

Referring to FIG. 2D, a plurality of electronic elements 24 are disposed on the second substrate 22 such that the electronic elements 24 and the second substrate 22 form a second packaging structure 2b. Further, an encapsulant 25 is formed between the substrate units 22a and the first substrate 21.

In the present embodiment, each of the substrate units 22a has a plurality of electronic elements 24 disposed thereon.

Each of the electronic elements 24 can be an active element such as a semiconductor chip, or a passive element such as a resistor, a capacitor or an inductor.

The electronic element 24 is electrically connected to the second substrate 22 (or the substrate unit 22a) in a flip-chip manner or through wire bonding. Further, the encapsulant 25 fills the space between the second substrate 22 and the first substrate 21.

Referring to FIGS. 2E and 2E′, a singulation process is performed and the carrier 29 is removed.

In the present embodiment, the singulation process is performed along the connecting portions 22b to partially remove the connecting portions 22b. As such, the cleaning holes 220 are partially removed to form notches 260. Each of the substrate units 22a and the remaining connecting portion 22b′ form a substrate 26 located over the first substrate 21.

Depending on the shape of the cleaning holes 220, 220′ , the shape of the notches 260. 260′ can be varied. Referring to FIG. 2E′, bent-shaped notches 260 are formed from the cross-shaped cleaning holes 220 of FIG. 2B and curved-shaped notches 260′ are formed from the circular-shaped cleaning holes 220′ of FIG. 2B′. In other embodiments, the notches can be of a bent shape, a curved shape, a linear shape or a polygonal shape.

In other embodiments, the connecting portions 22b and the cleaning holes 220, 220′ can be completely removed.

The cleaning holes 220, 220′ facilitate to disperse thermal stresses so as to prevent the first substrate 21 and the second substrate 21, 22 from warping during a chip-bonding or encapsulating process, thereby reducing stresses induced by thermal expansion and contraction and applied on the joints between the supporting elements 23 and the first substrate 21 or the second substrate 22. Therefore, the present invention overcomes the conventional drawbacks of cracking of the supporting elements 23 and a short circuit therebetween.

The present invention further provides a substrate (the second substrate 22 of FIG. 2B), which has: a plurality of substrate units 22a; and a connecting portion 22b formed between and connecting the substrate units 22a and having at least a cleaning hole 220, 220′ penetrating therethrough.

In an embodiment, the cleaning hole 220, 220′ is of a cross shape, a circular shape, a strip shape or a polygonal shape.

In an embodiment, the connecting portion 22b serves as a cutting path. The present invention further provides a packaging structure (the second packaging structure 2b of FIG. 2D), which has: a substrate 22 having a plurality of substrate units 22a and a connecting portion 22b formed between and connecting the substrate units 22a, wherein at least a cleaning hole 220, 220′ is formed to penetrate the connecting portion 22b; and an electronic element 24 disposed on the substrate 22.

In an embodiment, the cleaning hole 220, 220′ is of a cross shape, a circular shape, a strip shape or a polygonal shape.

In an embodiment, the connecting portion 22b serves as a cutting path.

In an embodiment, the electronic element 24 is a semiconductor element.

The present invention further provides a semiconductor package 2 (as shown in FIG. 2E), which has: a first substrate 21; and a second substrate 26 disposed on the first substrate 21 through a plurality of supporting elements 23, wherein at least a notch 260, 260′ is formed at an edge of the second substrate 26.

At least a semiconductor element 20 can be disposed on the first substrate 21.

The notch 260, 260′ can be of a bent shape, a curved shape, a linear shape or a polygonal shape.

In an embodiment, an encapsulant 25 is formed between the second substrate 26 and the first substrate 21. The encapsulant 25 can fill space S between the second substrate 26 and the first substrate 21.

In an embodiment, each of the supporting elements 23 is a conductive element. The conductive element can comprise a solder material and a flux.

In an embodiment, at least an electronic element 24 is further disposed on the second substrate 26.

Therefore, the present invention allows a liquid to flow through the cleaning holes into the space between the first substrate and the second substrate so as to remove flux during the cleaning process. As such, no flux is left on the first substrate after the cleaning process.

Further, the cleaning holes facilitate to disperse thermal stresses so as to prevent warpage of the first substrate and the second substrate, thereby preventing cracking of the supporting elements.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for fabricating a semiconductor package, comprising the steps of:
providing a first substrate;
disposing a second substrate on the first substrate through a plurality of supporting elements, wherein the second substrate has at least a cleaning hole penetrating therethrough; and
performing a cleaning process to clean space between the second substrate and the first substrate through the cleaning hole.

2. The method of claim 1, wherein the first substrate has at least a semiconductor element disposed thereon.

3. The method of claim 1, wherein the second substrate has a plurality of substrate units and the cleaning hole is formed at an edge of the substrate units.

4. The method of claim 1, wherein the second substrate further has a connecting portion formed between and connecting the substrate units.

5. The method of claim 4, wherein the connecting portion serves as a cutting path.

6. The method of claim 4, wherein the cleaning hole is formed on the connecting portion.

7. The method of claim 1, wherein the cleaning hole is of a cross shape, a circular shape, a strip shape or a polygonal shape.

8. The method of claim 1, wherein each of the supporting elements is a conductive element.

9. The method of claim 8, wherein the conductive element comprises a solder material.

10. The method of claim 9, wherein the conductive element comprises a flux.

11. The method of claim 1, further comprising cleaning the supporting elements through the cleaning process.

12. The method of claim 1, wherein a liquid is used for the cleaning process.

13. The method of claim 12, wherein the liquid is water.

14. The method of claim 1, further comprising disposing at least an electronic element on the second substrate.

15. The method of claim 1, further comprising forming an encapsulant between the second substrate and the first substrate.

16. The method of claim 15, wherein the encapsulant fills the space between the second substrate and the first substrate.

17. A substrate, comprising:
a plurality of substrate units; and
a connecting portion formed between and connecting the substrate units and having at least a cleaning hole penetrating therethrough.

18. The substrate of claim 17, wherein the connecting portion serves as a cutting path.

19. The substrate of claim 17, wherein the cleaning hole is of a cross shape, a circular shape, a strip shape or a polygonal shape.

20. A packaging structure, comprising:
a substrate having a plurality of substrate units and a connecting portion formed between and connecting the substrate units, wherein at least a cleaning hole is formed to penetrate the connecting portion; and
an electronic element disposed on the substrate.

21. The structure of claim 20, wherein the connecting portion serves as a cutting path.

22. The structure of claim 20, wherein the cleaning hole is of a cross shape, a circular shape, a strip shape or a polygonal shape.

23. The structure of claim 20, wherein the electronic element is a semiconductor element.

24. A semiconductor package, comprising:
a first substrate; and
a second substrate disposed on the first substrate through a plurality of supporting elements, wherein at least a notch is formed at an edge of the second substrate.

25. The package of claim 24, wherein at least a semiconductor element is disposed on the first substrate.

26. The package of claim 24, wherein the notch is of a bent shape, a curved shape, a linear shape or a polygonal shape.

27. The package of claim 24, wherein each of the supporting elements is a conductive element.

28. The package of claim 27, wherein the conductive element comprises a solder material.

29. The package of claim 28, wherein the conductive element comprises a flux.

30. The package of claim 24, further comprising at least an electronic element disposed on the second substrate.

31. The package of claim 24, further comprising an encapsulant formed between the second substrate and the first substrate.

32. The package of claim 31, wherein the encapsulant fills space between the second substrate and the first substrate.
